(19) United States
(12) Patent Application Publication
(10) Pub. No.: US 2011/0305994 A1
(43) Pub. Date: Dec. 15, 2011

(54) NANO PLASMONIC PARALLEL LITHOGRAPHY

(76) Inventor: Lars Montelius, Lund (SE)

(21) Appl. No.: 13/202,099

(22) PCT Filed: Feb. 17, 2010
(86) PCT No.: PCT/EP10/51965

§ 371 Date: Aug. 18, 2011

Related U.S. Application Data
(60) Provisional application No. 61/153,382, filed on Feb. 18, 2009.

(51) Int. Cl. G03F 7/20

(52) U.S. Cl. 430/322

(57) ABSTRACT

A method for replicate a pattern from a pre-patterned surface to a final substrate with in parallel approach lithography, the pre-patterned surface comprises a transparent substrate having a pre-patterned suitable metal; the method comprising the steps of: covering the final substrate with a chemical composition (resist) that is sensitive to Plasmon emitted light or waves; bringing the pre-patterned surface and the final substrate together to a proximity distance in the nanometer range, preferably 0 to 30 nm or more preferably 0 to 10 nm from the surface; illuminating the pre-patterned surface with plasmonic emitted light or waves, and exposing the final substrate to the plasmonic emitted light or waves to make a replica from the said pre-patterned surface.

### FIELD OF INVENTION

The present invention relates generally to nano- and atomic-scale lithography, and more particularly to plasmonic parallel lithography, especially to the non-direct patterning.

### SUMMARY OF INVENTION

The present invention relates to a method for replicate a pattern from a pre-patterned surface to a final substrate with in parallel approach lithography. The pre-patterned surface comprises a transparent substrate having a pre-patterned suitable metal. The method comprises the steps of covering the final substrate with a chemical composition (resist) that is sensitive to Plasmon emitted light or waves; bringing the pre-patterned surface and the final substrate together to a proximity distance in the nanometer range, preferably 0 to 30 nm or more preferably 0 to 10 nm from the surface; illuminating the pre-patterned surface with plasmonic emitted light or waves, and exposing the final substrate to the plasmonic emitted light or waves to make a replica from the said pre-patterned surface.

According to one aspect, the pre-patterned surface can comprise a pattern of nano- or microstructures on a transparent substrate.

According to one aspect, the transparent substrate can be transparent to the illuminating wavelength of the plasmonic emitted light or waves.

According to one aspect, the pattern can be defined by a metal layer.

According to one aspect, the metal layer can have a thickness of between 0.1 and 100 nanometer.

According to one aspect, the metal layer can be made from a metal having the properties needed for a plasmonic resonance to occur.

According to one aspect, the metal layer can be made of Cu, Ag, Au, Ni, and/or Co.

According to one aspect, the Plasmon waves (light) may be produced only on the surface of the pre-patterned surface in the range of several nanometer, preferably 0 to 10 nm, or more preferably 0 to 30 nm, from the surface, the wavelength of emitted Plasmon waves (light) can be dependent on the material, the patterns on the surface and the illumination condition

### BRIEF DESCRIPTION OF THE DRAWINGS

FIG. 1 disclose a schematic drawing of a earner and structured layer.

FIG. 2 disclose a schematic drawing of a carrier and structured layer.

FIG. 3 disclose a schematic drawing of a carrier and structured layer.

### DETAILED DESCRIPTION

There is a growing interest in the sub-wavelength control and manipulation of electromagnetic energy at optical frequencies (nano- photonics). A rapidly expanding branch of this field, plasmonics, aims at harnessing the unique properties of surface plasmon polaritons (SPPs) to miniaturize optical components to the nanoscopic dimensions of their electronic counterparts. Metallic nanostructures can also be fabricated to concentrate and locally enhance the electromagnetic fields by orders of magnitude. This effect is achieved by either engineering the metallic nanostructures to function as optical antennas or by controlling the illumination conditions to launch SPPs at a metal-vacuum or metal-dielectric interface.

The laws of physics dictate that the lenses used to direct light beams cannot focus them onto a spot whose diameter is less than half the light's wavelength. But converting the light into waves called plasmons can get around this limitation. Plasmonic lithography, which uses plasmon-generated radiation to carve physical features into a substrate.

When the silver nanoparticles are loosely packed, the structures behave like photonic crystals, allowing some wavelengths of light to propagate and stopping others. When the nanoparticles are densely packed, the structures take on entirely new optical properties, behaving as so-called plasmonic crystals. At the edges of the silver particles, surface energy waves called plasmons become concentrated. Just as photonic crystals allow some photons to pass while restricting others, the new crystals control the flow of the energy contained in light in the form of plasmons.

The main theme of the invention is surfaces and thin layers with extraordinary electromagnetic properties, which are realized by resonant surface structures. In the microwave region, this kind of structures has been investigated, manufactured and put into commercial use since some decades. Using the emerging nanotechnology, these designs are now be scaled to terahertz, infrared and optical frequencies, which promise new means of controlling the propagation, absorption and reflection of waves with wavelengths down to the visible region. In addition, the high field strengths typical of resonant structures open up the possibilities of improved sensor technology, utilizing the resonant surface structure to increase the sensitivity of a measurement system based on for instance, surface enhanced Raman scattering.

When the frequency of the electromagnetic radiation is increased from the microwave range to the optical range, metals cannot be treated as perfect electric conductors anymore. The plasmon frequencies of for example gold and silver lie just above the visible frequencies, and hence these metals show a strong dispersion in the permittivity in the visible range. For this reason pure down-scaling of structures, showing resonances in the microwave range, to the nanoscale is not straight-forward and more elaborate methods are needed for designing resonant structures in the optical range. Many of the ideas from the microwave range can however be used as guidelines also in the optical range. The method we use for the optical range is developed in-house, frequency domain method that takes into account the finite conductivity of metals through tabulated values of the frequency dependent permittivity. The method is designed especially for periodic structures, but it can be used for more general nanostructures including a-periodic systems.

Transmission of electromagnetic energy though sub-wavelength apertures in an opaque screen has recently attracted much interest. It is well known that the transmission through a single circular aperture is negligible if the wavelength is much larger than the dimensions of the aperture. Extraordinary transmission can e.g. occur for periodic arrays of apertures, corrugated surroundings of the aperture, and for resonant apertures (such as surface plasmon resonances). These properties resemble the frequency selective surfaces and aperture antennas in the microwave range.

Nano antennas for optical frequencies have several promising applications and can eventually lead to photonic wireless that brings various nano-elements together. These antennas are based on plasmonics but are conceptually similar to the classical microwave components. The optical circuits i.e. sub-wavelength metamaterial structures that manipulate the local electromagnetic field similar to the way lumped elements controls voltages and currents in classical electronics may lead to the possibility applying the mathematical machinery of circuit theory and information processing at optical frequencies. The two-dimensional arrays of various metal nano-wires with diameters ranging from 15 to 70 nm have been fabricated by electrodepositing metals of Cu, Ag, Au, Ni, and Co into the nano-holes of the anodic aluminum oxide (AAO) films, followed by partial removal of the film. The strong surface-enhanced Raman scattering (SERS) effects were observed from the metal nano-wire arrays including Ni, Co metals that were normally considered to be non-SERS active substrates. (J. L. YAO et al., Pure App. Chem., Vol. 72, No. 1, pp. 221-228,2000).

A maskless nanolithography that uses an array of plasmonic lenses that flies above the surface to be patterned, concentrating short-wavelength surface plasmons into sub-100 nm spots. These spots are only formed in the near-field. “Flying plasmonic Lens in the Nearfield for High-Speed Nanolithography”, Werayut Srituravanich, et al, Nature Nanotechnology 3, 733-737 (2008).

With the state of the art nanofabrication equipments, single-layer and multiple-layer thin metal films with sub-wavelength patterns of a nanometer-scale precision have been fabricated. Atomic layer deposition (ALD) and various thermal evaporation techniques were employed to make a variety of thin film structures, including single-metal films, metal/dielectric double-layer films, metal/dielectric multiple-layer films, etc. Sub-wavelength periodic structures were created on the thin films by lithography, focus-ion beam lithography, nanoimprint lithography, etc. A top-down method based on fabricated metal nanostructures to achieve super-sensitive surface-enhanced spectroscopy (SES) and surface plasmon resonance (SPR) sensors are primarily used.

Theoretical studies in the optical range is how structured thin films interacting with light can be used to exploit varying types of optical resonances for novel optical properties. These properties include the ability to tailor the dependence of the optical transport, i.e., the reflectance, the transmittance and the absorptance, with respect to the frequency, the polarization and the angle of incidence of incident light. Furthermore, the possibility for excitation and control of surface waves, near-field enhancement, and more exotic properties such as negative index of refraction, cloaking and perfect lenses opens also up.

In corrugated metal films surface plasmons (SPs) can be launched when the film is illuminated by light. These SPs are traveling waves that can be used to couple distant locations of the film, for example for information carrying purposes. The propagation of the SPs can be controlled by planar structures, while the excitation strength of the SPs depends on the type of corrugation, and the form of the incident light. An isolated metal particle can also exhibit resonances, so called localized surface plasmons (LSPs). At these resonances the near-field shows strong enhancement and localization to a region of only a few tens of nanometers around the particles, which is of interest and importance for non-linear optical phenomena. The transport properties of a dielectric film can be dramatically altered, in a controllable manner, if LSP-active metal particles are positioned on top, or inside, the film. Similarly the optical response of periodically corrugated metal films can be tuned by changing the type of corrugation, where the largest tunability comes from adjusting SP resonances. It is not only the frequency response, but also the polarization dependence, and the dependence on the angle of incidence of the incident light, which can be controlled to a high degree by changing structural dimensions and shapes, as well as the constituent materials. In multi-layered thin films, where the different layers are dielectric, metallic, and SP active or LSP active, an even larger spectrum of possible controllable properties shows up. In these structures the dielectric layers can support guided modes, and the interaction of the many, different kinds of possible resonances gives the opportunity for a very high tunability. In these meta materials the possibility for exotic properties, such as a negative index of refraction, perfect lenses, planar lenses and optical cloaking, is expected.

As described above, interaction between electromagnetic fields and sub-wavelength structures occur in many material problems from nano structures with visible light to ordinary antennas at microwave frequencies. A set of new bounds based on sum rules for the scattering and absorption cross-sections have recently been applied to meta-materials and antennas, and it offers accurate estimates on the frequency characteristics of the sub-wavelength interaction.

Scaling the design know-how from the microwave range is relatively straight-forward since the material models do not change very much, which makes it possible to construct important components such as absorbers, band pass and band stop filters, and even array antennas for THz applications.

Generally it is assumed that quantum systems are very fragile and short lived. In fact this is not necessarily true. Photons in general are fantastically robust carriers of quantum information and, as far as we know, information encoded into quantum states of light may be transmitted unperturbed across thousands of light years. However photon-photon interaction is exceedingly weak and logical operations, for classical optical computing as well as for quantum computing, need to be carried out by involving also other types of interactions.

The SP phenomena, which form the basis of nano plasmonic devices, are collective charge fluctuations occurring on nanometer length and femto/attosecond time scales. Spatial extent is determined by length scales in the resonant (nano) structures, temporal scales are determined by dephasing times and collective motion in nano plasmonic systems which unfolds on the femtosecond and even attosecond timescales. Consequently measurement techniques with nanoscale spatial and attosecond temporal resolution are highly desirable. However, the simultaneous imaging of SP modes on their fundamental temporal and spatial timescales is by no means trivial and has not been achieved by optical methods.

To radically increase our diagnostics capabilities we therefore combined Photoemission Electron Microscopy (PEEM) and attosecond XUV/IR laser technology to directly image surface plasmon dynamics with attosecond time resolution and nanometer lateral resolution. This technique will not disturb the nano plasmonic fields it is probing, and should in principle allow for direct control of ultra fast processes in surface plasmonnanosystems. The feasibility and importance of this concept has also been described by Stockman, et al from MPI—Quantenoptik (Nature Photon. 1, (2007) 539).

In an elegant combination of plasmon enhancement and diagnostics development we used resonant plasmon enhancement provided by an array of nanostructures, for high order harmonic generation as demonstrated recently (S. Kim et al., Nature, 453,(2008) 757). Due to the resonant effect, the laser intensity required to generate the high harmonics is a factor of 1000 less than normally needed. As a result, harmonics can be produced using a simple laser oscillator. This could enable the production of very compact and relatively cheap and very useful coherent XUV sources, with laser-like properties, ultra short duration, and MHz repetition rates of interest for many applications. With this development our atto-PEEM diagnostic tool could potentially develop into a standard tool for evaluation of electro-magnetically active structures.

The list below is a summaries that make the background of the this invention:
In corrugated metal films Surface Plasmons (SPs) can be launched when the film is illuminated by light.
An isolated metal particle can also exhibit resonances, so called Localized Surface Plasmons (LSPs).
At these resonance's, the near-field shows strong enhancement and localization to a region of only a few tens of nanometers around the metal surface, which is of interest and importance for non-linear optical phenomena
The propagation of the SPs can be controlled by planar structures, while the excitation strength of the SPs depends on the type of corrugation, and the form of the incident light.

The invention describes a method to replicate a pattern from a pre-patterned surface to final substrates. The technology uses Raman-Scattering waves produced in nanometer size patterns layer so called Plasmon waves. This Plasmon waves (light) is produced only on the surface of material in the range of several nanometer close proximity from the surface. The wavelength of emitted waves (light) is dependent on material, the pattern on the surface and the illumination light condition. In this process a carrier object is covered by a chemical composition sensitive for Plasmon emitted light or waves. A glass substrate is pre- patterned using a suitable metal or semiconductor material acting as mask. The mask and the final substrate bring together to a proximity distance in the nanometer range. The mask will be illuminated using a high power light source. This illumination causes emission of Plasmon light on the surface of the mask. This Plasmonic light will thereafter expose the final substrate to produce a replica from the mask. This process will produce a replica on the whole surface of substrate at once and it is meant to be a parallel lithography approach, in comparison to a direct write or maskless lithography.

The distance between the mask substrate and the final substrate to be patterned may be between 0 to 30 nm in order to use the effect of the emitted Plasmon light.

The mask is made of a transparent substrate and it is covered with thin layer of e.g metals of Cu, Ag, Au, Ni, and Co, where the pattern are defined through a serial (direct) write lithography technology and plasma etching or self-assembly into the mask cover material. The Plasmonic effect is produced in the chink between the patterns of the cover material. The pattern defined on the mask is removed parts from the cover layer. The spaces in the pattern then will be smaller than wavelength of the illuminated light in order to eliminate the effect of the illuminated light effect, in the process. The spacing is in the range of sub 100 nanometer.

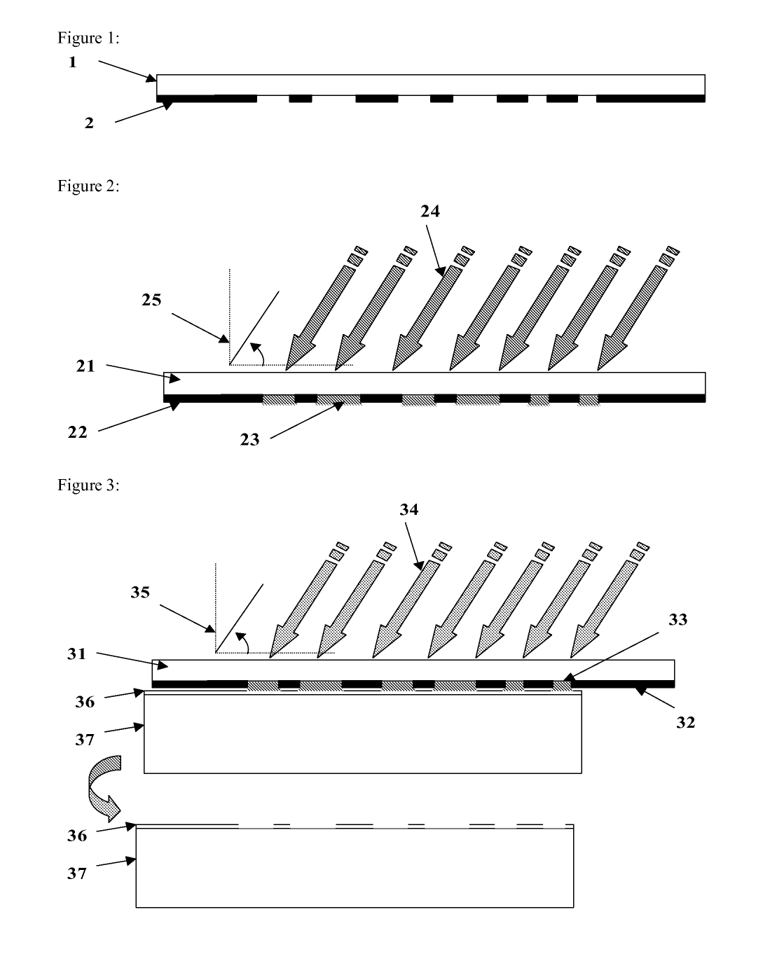

FIG. 1 disclose a pre-patterned surface comprising a transparent carrier (1), e.g. glass substrate, and a final substrate (2) with a structured metallic layer.

FIG. 2 disclose a light illumination source (24) to produce a Plasmon light (23) in a structured metal layer (22). The light exposes the structured metal layer (22) with an angle (25) through a transparent carrier (21)

FIG. 3 disclose a light illumination source (34) to produce a Plasmon emitted light (33) in the structured metal layer (32). The light exposes the metal layer (32) with an angle (35) through a transparent carrier substrate (31) and the metal layer emitters Plasmon light (33). The Plasmon emitted light (33) will expose partial area of the light sensitive layer (36), which is carried on the wafer (37).

The scope of protection sought is defined in the appended claims.

1. A method for replicating a pattern from a pre-patterned surface to a final substrate with in parallel approach lithography, the pre-patterned surface comprises a transparent substrate having a pre-patterned suitable metal; the method comprising the steps of:
covering the final substrate with a chemical composition (resist) that is sensitive to Plasmon emitted light or waves;
bringing the pre-patterned surface and the final substrate together to a proximity distance in the nanometer range, from the surface;
illuminating the pre-patterned surface with plasmonic emitted light or waves, and exposing the final substrate to the plasmonic emitted light or waves to make a replica from the said pre-patterned surface.

2. The method according to claim 1, wherein the pre-patterned surface comprises a pattern of nano- or microstructures on a transparent substrate.

3. The method according to claim 2, wherein the transparent substrate is transparent to the illuminating wavelength of the plasmonic emitted light or waves.

4. The method according to claim 1, wherein the pattern is defined by a metal layer.

5. The method according to claim 1, wherein the metal layer has a thickness of between 0.1 and 100 nanometer.

6. The method according to claim 1, wherein the metal layer is made from a metal having the properties needed for a plasmonic resonance to occur.

7. The method according to claim 6, wherein the metal layer is made of Cu, Ag, Au, Ni, and/or Co.

8. The method according to claim 1, wherein the Plasmon waves (light) is produced only on the surface of the pre-patterned surface in the range of 0 to 10 nm, from the surface, the wavelength of emitted Plasmon waves (light) is dependent on the material, the patterns on the surface and the illumination condition.
